(19) United States
(12) Patent Application Publication
(10) Pub. No.: US 2009/0267459 A1
(43) Pub. Date: Oct. 29, 2009

(54) COMPOSITE MATERIAL VIBRATOR

(75) Inventors: Yuya Yamada, Shiga-ken (JP); Akihiko Kawakami, Shiga-ken (JP); Koji Matsushita, Shiga-ken (JP); Shinsuke Uchida, Shiga-ken (JP)

Correspondence Address: MURATA MANUFACTURING COMPANY, LTD.;C/O KEATING & BENNETT, LLP, 1800 Alexander Bell Drive, SUITE 200, Reston, VA, 20191, US

(73) Assignee: MURATA MANUFACTURING CO., LTD., Nagaokakyo-shi, Kyoto-fu (JP)

(21) Appl. No.: 10/595,923

(22) PCT Filed: Nov. 17, 2004
(86) PCT No.: PCT/JP2004/017054

§ 371 Date: Aug. 16, 2007

(30) Foreign Application Priority Data
Nov. 20, 2003 (JP) 2003-391388

(51) Int. Cl. H03H 9/17

(52) U.S. Cl. 310/345

(57) ABSTRACT

A composite material vibrator includes a vibrating component that is composed of a material having a first acoustic impedance Z₁ and that serves as a vibration source, a reflective layer that is composed of a cured product of a resin composition including at least a curable resin curable by heat, a curing agent, and a silicone compound, the cured product having a second acoustic impedance Z₂ that is lower than the first acoustic impedance Z₁ and that is connected to the vibrating component, and a holding component that is composed of a material having a third acoustic impedance Z₃ that is higher than the second acoustic impedance Z₂ and that is connected to surface of the reflective layer, the surface being opposite to the surface connected to the vibrating component, wherein vibration propagated from the vibrating component to the reflective layer is reflected at the interface between the reflective layer and the holding component.

### BACKGROUND OF THE INVENTION

1. Field of the Invention

The present invention relates to a composite material vibrator in which a plurality of elements composed of materials having different acoustic impedances are combined. For example, the present invention relates to a composite material vibrator in which reflective layers having a low sound velocity and a low damping are connected to a vibrating component such as a piezoelectric element.

2. Description of the Related Art

As piezoelectric resonating components constituting a piezoelectric resonator, a piezoelectric filter, or the like, a component prepared by laminating case substrates on and under a piezoelectric vibrating element has been widely used. In such a case, a space for allowing for free, uninhibited vibration of the piezoelectric vibrating portion of the piezoelectric element must be provided in the laminate. For this purpose, the following methods have been used. In one method, a recess for forming a cavity is formed on a surface of a case substrate to be laminated, the surface being adjacent to the piezoelectric element. In another method, in laminating the case substrates on the piezoelectric element, in order to form a cavity, an area on which an adhesive is applied is formed on an area except for the cavity.

As described above, in the known laminated piezoelectric resonating components, a cavity for allowing for free vibration of the piezoelectric vibrating portion must be provided. Therefore, is has been difficult to reduce the size of the component and to reduce the cost.

On the other hand, a laminated structured bulk acoustic wave filter that does not include a cavity is disclosed (see Japanese Unexamined Patent Application Publication No. 10-270979). As shown in FIG. 3 of this reference, in a bulk acoustic wave filter 211, a plurality of films are laminated on a substrate 212 to form a piezoelectric filter.

In this laminated structure, a piezoelectric layer 213 is provided, and electrodes 214 and 215 are laminated on the upper surface and the lower surface of the piezoelectric layer 213, respectively, to form a piezoelectric resonator.

An acoustic mirror 219 is provided on the lower surface of the piezoelectric resonator. The acoustic mirror 219 has a laminated structure including an upper layer 216, an interlayer 217, and a lower layer 218, the structure being formed by laminating films composed of silicon, polysilicon, or the like. Another acoustic mirror 220 having a similar laminated structure is laminated on the upper surface of the piezoelectric resonator. A passivation film 221 functioning as a protective film is provided on the acoustic mirror 220.

In the acoustic mirror 219, the impedance of the interlayer 217 is higher than that of the upper layer 216 and that of the lower layer 218. Similarly, in the acoustic mirror 220, the impedance of the interlayer is higher than that of the upper layer and that of the lower layer.

In the bulk acoustic wave filter 211, by laminating the acoustic mirrors 220 and 219 on and under the piezoelectric resonator portion, respectively, vibrations propagated from the piezoelectric resonator are reflected to the side of the piezoelectric resonator. Accordingly, the piezoelectric resonator can be mechanically held using the substrate 212 without affecting the resonance characteristics of the piezoelectric resonator portion.

On the other hand, Japanese Unexamined Patent Application Publication No. 2002-164764 discloses a composite material vibrator in which holding components are connected to a piezoelectric element serving as a vibrating component with reflective layers each having an acoustic impedance lower than that of the piezoelectric element therebetween. In this vibrator, the acoustic impedance Z₂ of the reflective layers is lower than the acoustic impedance Z₁ of the piezoelectric element, and is lower than the acoustic impedance Z₃ of the holding components. Vibrations propagated from the piezoelectric element to the reflective layers are reflected at the interfaces between each of the reflective layers and the corresponding holding component. Therefore, it is believed that the piezoelectric element can be supported without requiring a large vibration damping region. According to the above-mentioned prior art, the reflective layers are composed of, for example, an epoxy resin.

In the bulk acoustic wave filter 211 shown in FIG. 3 of Japanese Unexamined Patent Application Publication No. 10-270979, the acoustic mirrors 219 and 220 are formed so that vibrations propagated from the side of the piezoelectric resonator are reflected. However, each of the acoustic mirrors 219 and 220 includes the upper layer, the lower layer, and the interlayer laminated therebetween, and the impedance of the interlayer is higher than that of the upper layer and that of the lower layer. Therefore, a large number of material layers must be laminated to form the acoustic mirrors 219 and 220. Thus, although the formation of a cavity can be omitted, a large number of material layers must be laminated in the bulk acoustic wave filter 211. Therefore, it is difficult to reduce the size, in particular, the thickness of the acoustic wave filter. The production process is also complex.

Furthermore, in the bulk acoustic wave filter 211, lateral vibrations of the piezoelectric resonator are propagated, but the vibrations alternately propagated are damped in the lateral portions of the piezoelectric resonator. Accordingly, since the lateral portions of the piezoelectric resonator are fixed, this holding structure degrades the resonance characteristics of the piezoelectric resonator.

In the composite material vibrator described in Japanese Unexamined Patent Application Publication No. 2002-164764, as described above, holding components are connected to a piezoelectric element with reflective layers each having a relatively low acoustic impedance Z₂ therebetween. Therefore, it has been believed that the piezoelectric element can be supported by the holding components without affecting the characteristics of the piezoelectric element.

However, when the reflective layers are formed using an epoxy resin, the piezoelectric element cannot necessarily be supported mechanically without suppressing a decrease in electrical characteristics of the piezoelectric element. In other words, even when the holding components are connected to the piezoelectric element with the reflective layers therebetween, it may be difficult to obtain satisfactory electrical characteristics.

### SUMMARY OF THE INVENTION

In order to overcome the problems described above, preferred embodiments of the present invention provide a composite material vibrator that has a relatively simple structure, that can be supported without hardly affecting the vibration characteristics of the vibrating component, that can be easily reduced in size, and that has excellent electrical characteristics.

A composite material vibrator according to a preferred embodiment of the present invention includes a vibrating component that is composed of a material having a first acoustic impedance Z₁ and that serves as a vibration source, a reflective layer that is composed of a cured product of a resin composition including at least a curable resin curable by heat, a curing agent, and a silicone compound, the cured product having a second acoustic impedance Z₂ that is lower than the first acoustic impedance Z₁ and that is connected to the vibrating component, and a holding component that is composed of a material having a third acoustic impedance Z₃ that is higher than the second acoustic impedance Z₂ and that is connected to surfaces of the reflective layer, the surface being opposite to the surface connected to the vibrating component, wherein vibration propagated from the vibrating component to the reflective layer is reflected at the interface between the reflective layer and the holding component.

According to a specific preferred embodiment of the composite material vibrator of the present invention, the curable resin is preferably an epoxy resin.

According to another specific preferred embodiment of the composite material vibrator of the present invention, the silicone compound is preferably included in the resin composition in an amount of about 6 percent by weight to about 60 percent by weight.

According to another specific preferred embodiment of the composite material vibrator of the present invention, the silicone compound is preferably a silicone rubber powder coated with a polyorganosilsesquioxane cured product.

In the composite material vibrator of a preferred embodiment of the present invention, preferably, the sound velocity in the reflective layer at 5 MHz is about 2,600 m/s or less and the damping coefficient of the reflective layer at 5 MHz is about 3.5 dB/mm or less.

In a method for producing a composite material vibrator according to yet another preferred embodiment of the present invention, a method for obtaining the above-described composite material vibrator of the present invention includes the steps of preparing the vibrating component and the holding components, preparing an uncured resin composition containing at least a curable resin curable by heat, a curing agent, and a silicone compound, laminating the vibrating component and the holding component with the uncured resin composition, and curing the uncured resin composition to form the reflective layer connected to the vibrating component and the holding component.

According to another specific preferred embodiment of the method for producing a composite material vibrator according to the present invention, the production method includes the steps of preparing the vibrating component and the holding component, preparing a resin sheet containing at least a thermosetting resin, a curing agent, and a silicone compound, disposing the resin sheet between the vibrating component and the holding component, and curing the resin sheet to form the reflective layer connected to the vibrating component and the holding component.

In the production method according to a preferred embodiment of the present invention, the curing of the resin composition is preferably performed by heating.

According to the composite material vibrator of a preferred embodiment of the present invention, the reflective layer can be formed by merely curing a resin and a plurality of material layers need not be laminated. Consequently, the production process can be simplified. Since the resin used in the reflective layer also has adhesiveness, the reduction in thickness, the reduction in size, and the reduction in cost of the composite material vibrator can be achieved. Furthermore, since the reflective layer of the composite material vibrator according to various preferred embodiments of the present invention have a low sound velocity and a low damping, electrical characteristics of the composite material vibrator can be improved.

Other features, elements, steps, characteristics and advantages of the present invention will become apparent from the following detailed description of preferred embodiments thereof with reference to the attached drawings.

### BRIEF DESCRIPTION OF THE DRAWINGS

FIG. 1 is an exploded perspective view of a composite material vibrator according to a preferred embodiment of the present invention.

FIG. 2 is a perspective view showing the appearance of the composite material vibrator according to a preferred embodiment of the present invention.

FIG. 3 is a longitudinal cross-sectional view showing a bulk acoustic wave filter, which is a known composite material vibrator.

### DETAILED DESCRIPTION OF PREFERRED EMBODIMENTS

A composite material vibrator according to a preferred embodiment of the present invention will now be described.

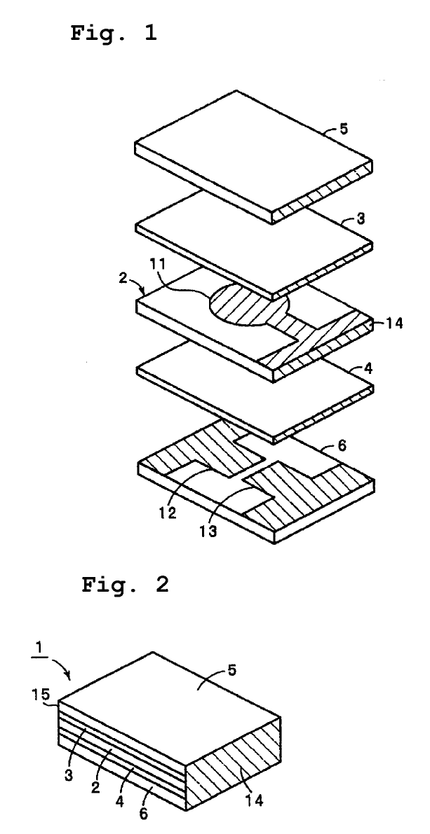

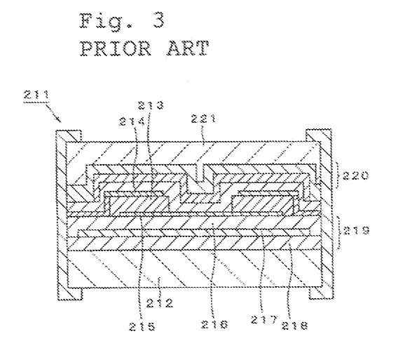

FIG. 1 is an exploded perspective view of a composite material vibrator according to a first preferred embodiment of the present invention, and FIG. 2 is a perspective view showing the appearance thereof.

In a composite material vibrator 1 of the present preferred embodiment, a piezoelectric resonator 2 is preferably used as a vibrating component, for example. The piezoelectric resonator 2 preferably includes a substantially rectangular lead zirconate titanate piezoelectric ceramic plate. This ceramic plate is subjected to a polarization treatment in the thickness direction. An excitation electrode 11 is provided at the approximate center of the upper surface of the ceramic plate. Although not shown in FIG. 1, another excitation electrode is provided at the approximate center of the lower surface of the ceramic plate. The excitation electrode 11 and the other excitation electrode provided on the lower surface extend to end surfaces of the ceramic plate and are electrically connected to outer electrodes 14 and 15, respectively.

The piezoelectric resonator 2 is excited in the thickness-shear vibration mode by applying an alternating voltage between the excitation electrode 11 and the other excitation electrode provided on the lower surface. The ceramic plate preferably has an acoustic impedance Z₁ of approximately 18.8×10⁶ N·s·m⁻³.

A first reflective layer 3 and a second reflective layer 4 are laminated on the upper surface and the lower surface of the piezoelectric resonator 2, respectively. A first holding component 5 and a second holding component 6 are laminated on the outer surfaces of the reflective layers 3 and 4, respectively, that is, on the surfaces opposite to the surfaces on which the piezoelectric resonator 2 is connected. The reflective layers 3 and 4 are composed of a material that can be adhered by drying, heating, chemical reaction, or the like.

More specifically, in an example of the present preferred embodiment, the reflective layers 3 and 4 are preferably composed of a material prepared by curing a resin composition containing at least a thermosetting resin, a curing agent, and a silicone compound, and have an acoustic impedance Z₂ of approximately 3.1×10⁶ N·s·m⁻³ or less, for example. Furthermore, the sound velocity in the reflective layers 3 and 4 at 5 MHz is preferably about 2,600 m/s or less, and the damping coefficient of the reflective layers 3 and 4 at 5 MHz is preferably about 3.5 dB/mm or less. Thereby, a composite material vibrator having excellent electrical characteristics can be obtained.

In the present preferred embodiment, each of the holding components 5 and 6 preferably includes a substantially rectangular ceramic plate, and preferably has an acoustic impedance Z₃ of about 18.8×10⁶ N·s·m⁻³. A pair of capacitor electrodes 12 and 13 is provided on the upper surface of the lower holding component 6. Other capacitor electrodes (not shown in the figure) are provided at the approximate center of the lower surface of the holding component 6 so as to face the capacitor electrodes 12 and 13 with the holding component 6 disposed therebetween. The capacitor electrodes 12 and 13 and the other capacitor electrodes provided on the lower surface define a capacitor on the holding component 6.

The outer electrode 14 shown in FIG. 2 is provided on an end surface of the laminate prepared by laminating the components shown in FIG. 1. In addition, the outer electrode 15 is provided on the other end surface of the laminate. The outer electrodes 14 and 15 are electrically connected to the excitation electrode 11 of the piezoelectric resonator 2 and the other excitation electrode disposed on the lower surface, respectively.

The outer electrodes 14 and 15 are also electrically connected to the capacitor electrodes 13 and 12, respectively. Thus, by electrically connecting the outer electrodes 14 and 15 to the capacitor electrodes provided on the lower surface of the holding component 6 and the outside, the composite material vibrator 1 operates as a three-terminal piezoelectric oscillator with a built-in capacitor.

In the composite material vibrator 1 of the present preferred embodiment, the first and second reflective layers 3 and 4 are connected to the upper surface and the lower surface of the piezoelectric resonator 2 serving as a vibrating component, respectively. In addition, the holding components 5 and 6 are connected to the surfaces of the reflective layers 3 and 4, respectively, the surfaces being opposite to the surfaces on which the piezoelectric resonator 2 is connected. Therefore, a cavity for not interfering with the vibration of the piezoelectric resonator 2 is not provided. Thus, since such a cavity need not be formed, the reduction in thickness, the reduction in size, and the reduction in cost can be achieved.

The curable resin used in the reflective layers of the present invention is not particularly limited as long as the resin is cured by heating. The form of the curable resin at room temperature is also not particularly limited and the curable resin may be a liquid or a solid at room temperature. Examples of the thermosetting resin include epoxy resins, urethane resins, vinyl ester resins, phenolic resins, urea resins, melamine resins, unsaturated polyester resins, diallyl phthalate resins, and polyimide resins.

An epoxy resin is preferably used as the thermosetting resin. Thereby, excellent adhesive force and excellent reliability can be achieved. Examples of the epoxy resin include bisphenol epoxy resins, phenol novolak epoxy resins, cresol novolak epoxy resins, ortho-cresol novolak epoxy resins, alicyclic epoxy resins, biphenyl epoxy resins, aralkyl epoxy resins, halogenated epoxy resins, triphenolmethane epoxy resins, naphthalene novolak epoxy resins, aromatic amine epoxy resins, phenol-based multifunctional epoxy resins, and dicyclopentadiene phenol epoxy resins.

These epoxy resins may be used alone or in combinations of two or more resins.

The curing agent used in the reflective layers of various preferred embodiments of the present invention is an adequate compound that cures the curable resin. Examples of the curing agent used for thermosetting resins include amines, aliphatic polyamines, modified aliphatic polyamines, acid anhydrides, phenol, imidazoles, epoxy-imidazole adducts, amine adducts, and diaminodiphenyl sulfone. These curing agents may be used alone or as a mixture of two or more compounds.

In various preferred embodiments of the present invention, examples of the silicone compound used in the reflective layers include polydimethylsiloxane, polymethylphenylsiloxane, polydiphenylsiloxane, and polymethylsilsesquioxane. Resinoids, i.e., silicone resins may also be used as the silicone compound. The silicone compounds may be in the form of a liquid or in the form of a power. Powdery compounds are preferable because of their high heat resistance. These silicone compounds may be used alone or in combinations of two or more compounds.

The silicone compound used in the reflective layers of the present invention is preferably included in an amount of about 6 percent by weight to about 60 percent by weight in the resin composition constituting the reflective layers. When the content is less than about 6 percent by weight, electrical characteristics of the composite material vibrator tend to be degraded because the sound velocity in the resin composition is not decreased. On the other hand, when the content exceeds about 60 percent by weight, the viscosity of the resin composition is increased. As a result, the flowability of the resin composition is decreased during the formation of the reflective layers of the composite material vibrator. Thus, it may take a long time to form a desired shape.

In at least one of the preferred embodiments of the present invention, a silicone rubber powder coated with a polyorganosilsesquioxane cured product is preferably used as the silicone compound contained in the reflective layers. The polyorganosilsesquioxane cured product is a substance prepared by curing a polyorganosilsesquioxane by polymerization reaction. The polyorganosilsesquioxane cured product is represented by a general formula RSiO_{3/2}. In the formula, R represents at least one monovalent hydrocarbon group having 1 to 20 carbon atoms, the hydrocarbon group being selected from alkyl groups such as methyl, ethyl, propyl, butyl, pentyl, hexyl, heptyl, octyl, nonyl, decyl, dodecyl, tetradecyl, hexadecyl, octadecyl, and eicosyl groups; aryl groups such as phenyl and tolyl groups; alkenyl groups such as vinyl and allyl groups; aralkyl groups such as β-phenylethyl and β-phenylpropyl groups; monovalent halogenated hydrocarbon groups such as chloromethyl and 3,3,3-trifluoropropyl group; and hydrocarbon groups having reactivity, such as epoxy, amino, mercapto, acryloxy, and methacryloxy groups. The particle size of the silicone rubber powder coated with a polyorganosilsesquioxane cured product is not particularly limited but, for example, a powder having an average particle size of about 0.1 μm to about 100 μm is used.

When the silicone rubber powder coated with a polyorganosilsesquioxane cured product is added to the resin composition for the reflective layers, the amount added is preferably about 6 percent by weight to about 60 percent by weight of the total of the resin composition. When the amount is less than about 6 percent by weight, the effect by the addition of the silicone rubber powder, i.e., the effect of satisfactorily decreasing the sound velocity may be difficult to be achieved. On the other hand, when the amount exceeds about 60 percent by weight, the viscosity of the resin composition is increased. As a result, the flowability of the resin composition is decreased during the formation of the reflective layers of the composite material vibrator. Thus, it may take a long time to form a desired shape.

In addition to the above materials constituting the reflective layers of various preferred embodiments of the present invention, in order to impart the curability, the adhesiveness, the thixotropic property, or the like according to the intended use, inorganic fillers such as fused silica, crushed silica, silica fine particles, talc, and glass; inorganic fillers prepared by performing a surface treatment such as a hydrophobic treatment or a hydrophilic treatment on the above inorganic fillers; life stabilizers; coupling agents such as alkoxysilanes; leveling agents; diluents; flame retardants; lubricants; rheology-controlling agents; anti-settling agents; adhesiveness imparting agents; pigments; dispersing agents; antifoaming agents; or the like may be added.

In the production of the composite material vibrator according to various preferred embodiments of the present invention, when the above-described vibrating component and the holding component are connected with the reflective layer, a method of applying a resin composition for forming the reflective layer on at least one of the vibrating component and the holding component, bonding the vibrating component and the holding component with the resin composition provided therebetween, and curing the resin composition can used. The resin composition constituting the reflective layers may be provided in the form of a semi-cured adhesive sheet. In such a case, a resin composition including an appropriate sheet-forming material in addition to the curable resin, the curing agent, and the silicone compound is suitably used. When the resin composition prepared in the form of the semi-cured adhesive sheet is used, the semi-cured adhesive sheet is disposed between the vibrating component and the holding component and the resin composition provided in the form of the adhesive sheet is cured while these three components are in close contact with each other.

The method for curing the resin composition is not particularly limited. When the resin composition includes a curing agent that is activated by heat, the resin composition can be cured by heating. Thus, a curable resin such as an epoxy resin may be cured.

Experimental examples of preferred embodiments of the present invention will now be described.

### (1) Experimental Example 1

### (a) Preparation of Resin Cured Products

First, as starting materials for resin compositions used for the reflective layers, thermosetting resins 1 and 2, curing agent 1, and a silicone compound were prepared. In this experiment, thermosetting resin 1 was a p-aminophenol epoxy resin (epoxy equivalent= 97 g/eq), thermosetting resin 2 was a tetraglycidylaminodiphenylmethane epoxy resin (epoxy equivalent= 120 g/eq), curing agent 1 was 2-phenyl-4-methyl-5-hydroxymethyl imidazole, and the silicone compound used was a spherical silicone resin powder having an average particle size of about 2 μm, for example.

Next, these starting materials were weighed so as to prepare resin compositions having the compositions shown in Table 1. Mixing and vacuum mixing were performed with a planetary mixer to prepare resin compositions of Sample Nos. 1 to 5 shown in Table 1. Subsequently, each of the resin compositions was supplied in an ethylene fluoride resin mold and vacuum deaeration was performed. The resin compositions were then left to stand in an oven at 150° C. for one hour to prepare target resin cured products.

TABLE 1

| | Sample No. | | | | |
|---|---|---|---|---|---|
| | | | | | * |
| | 1 | 2 | 3 | 4 | 5 |
| Thermosetting resin 1 (g) | 65 | 65 | 65 | 65 | 65 |
| Thermosetting resin 2 (g) | 35 | 35 | 35 | 35 | 35 |
| Curing agent 1 (g) | 4 | 4 | 4 | 4 | 4 |
| Silicone compound (g) | 20 <16> | 45 <30> | 60 <37> | 75 <42> | 0 <0> |
| <Content in resin | | | | | |
| composition (wt %)> | | | | | |
| Sound velocity (m/s) | 2502 | 2343 | 2296 | 2221 | 2681 |
| Density (10³ · Kg/m³) | 1.25 | 1.26 | 1.26 | 1.27 | 1.25 |
| Damping coefficient | 2.68 | 2.09 | 2.17 | 1.98 | 3.60 |
| (dB/mm) | | | | | |
| Acoustic impedance | 3.1 | 3.0 | 2.9 | 2.8 | 3.4 |
| (10⁶ N · s · m⁻³) | | | | | |
| Electrical characteristics | Good | Good | Good | Good | Not |
| | | | | | good |

### (b) Preparation of Composite Material Vibrators

As shown in FIGS. 1 and 2, each of the uncured resin compositions of Sample Nos. 1 to 5 was applied on a piezoelectric resonator 2 composed of a ceramic having an acoustic impedance of about 18.8×10⁶ N·s·m⁻³. The resulting piezoelectric resonator 2 was laminated with holding components 5 and 6 each composed of a ceramic having an acoustic impedance of about 18.8×10⁶ N·s·m⁻³ and the laminate was left to stand in an oven at 150° C. for one hour to cure the resin composition. When the resin composition was applied, the application thickness was adjusted such that the thickness of the resin cured product (reflective layer) after curing corresponded to a quarter (λ/4) of the oscillation wavelength (λ) of the piezoelectric resonator. Subsequently, outer electrodes 14 and 15 shown in FIGS. 1 and 2 were formed to prepare target composite material vibrators.

### (c) Characteristic Evaluation of Resin Cured Products

The sound velocity, the damping coefficient, the density, and the acoustic impedance of the resin cured products prepared in section (a) were evaluated.

Regarding the sound velocity (m/s), a value (of longitudinal waves) at 5 MHz was calculated from equation 1 with an ultrasonic viscoelasticity measuring instrument (RAM-10000, manufactured by RITEC).

Sound velocity=L/t Equation 1

In equation 1, L represents the thickness (m) of the resin cured product and t represents a time (s) required for the propagation of ultrasonic waves.

Regarding the damping coefficient (dB/mm), a value (of longitudinal waves) at 5 MHz was calculated from equation 2 with the ultrasonic viscoelasticity measuring instrument.

Damping coefficient={ln [(A₀²−A²)/A₀B]}/(17.372×L×10³) Equation 2

In equation 2, A₀ represents an amplitude (m) of reflected waves at the bottom surface of a cushioning material of the measuring instrument, A represents an amplitude (m) of reflected waves at the interface between the cushioning material and the resin cured product, B represents an amplitude (m) of reflected waves at the bottom surface of the resin cured product, and L represents the thickness (m) of the resin cured product.

The density (10³·kg/m³) was calculated from the weight (kg) and the volume (m³) of the resin cured product. Regarding the acoustic impedance (10⁶ N·s·m⁻³), a value (of longitudinal waves) at 5 MHz was calculated from equation 3 using the measured values of the density and the sound velocity.

Acoustic impedance=density×sound velocity Equation 3

### (d) Evaluation of Electrical Characteristics of Composite Material Vibrators

Electrical characteristics of the composite material vibrators prepared in section (b) were measured. As the electrical characteristics, the maximum value of the phase was measured. When the maximum value of the phase is large, the electrical characteristics are excellent. When the maximum value of the phase was about 78 degrees or more, the sample was evaluated as “Good” in Table 1. When the maximum value of the phase was less than about 78 degrees, the sample was evaluated as “Not good” in Table 1.

Table 1 shows the evaluation results described in sections (c) and (d). In Table 1, the sample marked with symbol * is out of the range of the preferred embodiments of the present invention and other samples are within the range of the preferred embodiments of the present invention.

As is apparent from Table 1, Sample Nos. 1 to 4, which contained the silicone compound showed low sound velocities, low damping coefficients, and satisfactory electrical characteristics. In contrast, in Sample No. 5, which did not contain the silicone compound, both the sound velocity and the damping coefficient were increased and the electrical characteristics were also degraded, as compared with those of Sample Nos. 1 to 4.

### (2) Experimental Example 2

### (e) Preparation of Resin Cured Products and Composite Material Vibrators

First, as starting materials of resin compositions used for the reflective layers, thermosetting resins 1 and 2 and the silicone compound, which were the same as those used in Example 1, were prepared. An epoxy-imidazole adduct serving as curing agent 2 and a carboxyl-group-terminated acrylonitrile-butadiene copolymer were prepared.

Next, these starting materials were weighed so as to prepare resin compositions having the compositions shown in Table 2. Mixing and vacuum mixing were performed with a planetary mixer to prepare resin compositions of Sample Nos. 6 to 11 shown in Table 2. Subsequently, target resin cured products were prepared as in section (a).

TABLE 2

| | Sample No. | | | | | |
|---|---|---|---|---|---|---|
| | | | | | | * |
| | 6 | 7 | 8 | 9 | 10 | 11 |
| Thermosetting resin 1 (g) | 100 | 100 | 100 | 100 | 100 | 100 |
| Thermosetting resin 2 (g) | 0 | 0 | 0 | 0 | 0 | 0 |
| Curing agent 2 (g) | 20 | 20 | 20 | 20 | 20 | 20 |
| Silicone compound (g) | 7 <6> | 14 <10> | 50 <29> | 70 <37> | 87 <42> | 0 <0> |
| <Content in resin | | | | | | |
| composition (wt %)> | | | | | | |
| Carboxyl-group-terminated | 0 <0> | 0 <0> | 0 <0> | 0 <0> | 0 <0> | 7 <6> |
| acrylonitrile-butadiene | | | | | | |
| copolymer (g) <Content | | | | | | |
| in resin composition (wt %)> | | | | | | |
| Sound velocity (m/s) | 2569 | 2497 | 2202 | 2164 | 2011 | 2638 |
| Density (10³ · Kg/m³) | 1.21 | 1.21 | 1.22 | 1.22 | 1.22 | 1.22 |
| Damping coefficient | 3.10 | 2.86 | 2.41 | 2.32 | 2.10 | 3.63 |
| (dB/mm) | | | | | | |
| Acoustic impedance | 3.1 | 3.0 | 2.7 | 2.6 | 2.5 | 3.2 |
| (10⁶ N · s · m⁻³) | | | | | | |
| Electrical characteristics | Good | Good | Good | Good | Good | Not |
| | | | | | | good |

Target composite material vibrators were also prepared as in section (b) using uncured resin compositions of Sample Nos. 6 to 11 shown in Table 2.

### (f) Evaluation of Characteristics of Resin Cured Products and Electrical Characteristics of Composite Material Vibrators

The sound velocity, the damping coefficient, the density, and the acoustic impedance of the resin cured products prepared in section (e) were evaluated as in section (c).

The electrical characteristics of the composite material vibrators prepared in section (e) were also evaluated as in section (d).

Table 2 shows the evaluation results of the resin cured products and the composite material vibrators. In Table 2, the sample marked with symbol * is out of the range of preferred embodiments of the present invention and other samples are within the range of preferred embodiments of the present invention.

As is apparent from Table 2, Sample Nos. 6 to 10, which contained the silicone compound showed low sound velocities, low damping coefficients, and satisfactory electrical characteristics. In contrast, in Sample No. 11, which did not contain the silicone compound but contained the carboxyl-group-terminated acrylonitrile-butadiene copolymer, both the sound velocity and the damping coefficient were increased and the electrical characteristics were also degraded, as compared with those of Sample Nos. 6 to 10.

### (3) Experimental Example 3

### (g) Preparation of Resin Cured Products and Composite Material Vibrators

First, as starting materials of resin compositions used for the reflective layers, thermosetting resins 1 and 2 and the silicone compound, which were the same as those used in Example 2 and polymethyl methacrylate were prepared. As curing agent 3, polyoxypropylenediamine (average molecular weight: 230, active hydrogen equivalent= 60 g/eq) was prepared.

Next, these starting materials were weighed so as to prepare resin compositions having the compositions shown in Table 3. Mixing and vacuum mixing were performed with a planetary mixer to prepare resin compositions of Sample Nos. 12 to 14 shown in Table 3. Subsequently, target resin cured products were prepared as in section (a).

TABLE 3

| | | | * |
|---|---|---|---|
| Sample No. | 12 | 13 | 14 |
| Thermosetting resin 1 (g) | 100 | 100 | 100 |
| Thermosetting resin 2 (g) | 0 | 0 | 0 |
| Curing agent 3 (g) | 58 | 20 | 20 |
| Silicone compound (g) | 237 | 164 | 0 |
| <Content in resin | <60> | <51> | <0> |
| composition (wt %)> | | | |
| Polymethyl methacrylate (g) | 0 | 0 | 164 |
| <Content in resin | <0> | <0> | <51> |
| composition (wt %)> | | | |
| Sound velocity (m/s) | 2075 | 2264 | 2000 |
| Density (10³ · Kg/m³) | 1.22 | 1.21 | 1.18 |
| Damping coefficient (dB/mm) | 3.30 | 3.50 | 4.50 |
| Acoustic impedance | 2.5 | 2.7 | 2.4 |
| (10⁶N · s · m⁻³) | | | |
| Electrical characteristics | Good | Good | Not |
| | | | good |

Target composite material vibrators were also prepared as in section (b) using uncured resin compositions of Sample Nos. 12 to 14 shown in Table 3.

### (h) Evaluation of Characteristics of Resin Cured Products and Electrical Characteristics of Composite Material Vibrators

The sound velocity, the damping coefficient, the density, and the acoustic impedance of the resin cured products prepared in section (g) were evaluated as in section (c).

The electrical characteristics of the composite material vibrators prepared in section (g) were also evaluated as in section (d).

Table 3 shows the evaluation results of the resin cured products and the composite material vibrators. In Table 3, the sample marked with symbol * is out of the range of preferred embodiments of the present invention and other samples are within the range of preferred embodiments of the present invention.

As is apparent from Table 3, Sample Nos. 12 and 13, which contained the silicone compound showed low sound velocities, low damping coefficients, and satisfactory electrical characteristics. In contrast, in Sample No. 13, which did not contain the silicone compound but contained polymethyl methacrylate, both the sound velocity and the damping coefficient were increased and the electrical characteristics were also degraded, as compared with those of Sample Nos. 11 and 12.

### (4) Experimental Example 4

### (k) Preparation of Resin Cured Products and Composite Material Vibrators

First, as starting materials of resin compositions used for the reflective layers, thermosetting resin 1 and curing agent 1, which were the same as those used in Example 1, were prepared. As a silicone compound, a silicone rubber powder coated with a polymethylsilsesquioxane cured product, the power having a Japanese Industrial Standard (JIS)-A hardness of 75 (JIS-K-6301) was prepared.

Subsequently, these starting materials were weighed so as to prepare resin compositions of Sample Nos. 17 to 20 having the compositions shown in Table 5. Mixing and vacuum mixing were performed with a planetary mixer to prepare resin compositions of Sample Nos. 17 to 20 shown in Table 4. Subsequently, target resin cured products were prepared as in section (a).

Target composite material vibrators were also prepared as in section (b) using uncured resin compositions of Sample Nos. 15 to 18 shown in Table. 4.

### (l) Evaluation of Characteristics of Resin Cured Products and Electrical Characteristics of Composite Material Vibrators

The sound velocity, the damping coefficient, the density, and the acoustic impedance of the resin cured products prepared in section (k) were evaluated as in section (c).

The electrical characteristics of the composite material vibrators prepared in section (k) were also evaluated as in section (d).

Table 4 shows the evaluation results of the resin cured products and the composite material vibrators. In Table 4, the sample marked with symbol * is out of the range of preferred embodiments of the present invention and other samples are within the range of preferred embodiments of the present invention.

TABLE 4

| | | | | * |
|---|---|---|---|---|
| Sample No. | 15 | 16 | 17 | 18 |
| Thermosetting resin 1 (g) | 100 | 100 | 100 | 100 |
| Curing agent 1 (g) | 4 | 4 | 4 | 4 |
| Silicone rubber powder | 47 | 58 | 72 | 0 |
| coated with | <31> | <36> | <41> | <0> |
| polyorganosilsesquioxane | | | | |
| cured product | | | | |
| <Content in resin | | | | |
| composition (wt %)> | | | | |
| Sound velocity (m/s) | 1900 | 1800 | 1750 | 2650 |
| Density (×10³ Kg/m³) | 1.18 | 1.15 | 1.13 | 1.28 |
| Damping coefficient (dB/mm) | 3.00 | 3.10 | 3.15 | 2.35 |
| Acoustic impedance | 2.2 | 2.1 | 2.0 | 3.4 |
| (×10⁶ N · s · m⁻³) | | | | |
| Electrical characteristics | Good | Good | Good | Not |
| | | | | good |

As is apparent from Table 4, Sample Nos. 15, 16, and 17, which included the silicone compound showed low sound velocities and satisfactory electrical characteristics. In contrast, in Sample No. 18, which did not include the silicone compound, the sound velocity was increased and the electrical characteristics were also degraded, as compared with those of Sample Nos. 15, 16, and 17.

### (5) Experimental Example 5

### (m) Preparation of Acoustic Reflection Resin Sheet

A bisphenol-A epoxy resin (epoxy equivalent= 190 g/eq) and o-cresol novolak epoxy resin (epoxy equivalent= 215 g/eq) that serve as thermosetting resins, phenol novolak (OH equivalent= 105 g/eq) serving as a curing agent, a polyvinyl butyral resin (weight-average molecular weight: 50,000) serving as a thermoplastic resin, a silicone resin powder (polymethylsilsesquioxane, average particle size: 2 μm) serving as a silicone compound, and methyl ethyl ketone serving as a solvent were prepared. These compounds were appropriately weighed as shown in Table 5, and were then mixed with a planetary mixer for one hour to prepare a slurry. The o-cresol novolak epoxy resin and the polyvinyl butyral resin were dissolved in methyl ethyl ketone serving as a solvent in advance and used. The slurry was subjected to vacuum deaeration. Subsequently, a sheet forming was performed by applying the slurry on a carrier film (polyethylene terephthalate (PET), thickness: 50 μm) at 50° C. so that the surface coated with the silicone was disposed at the upper side. Thus, an acoustic reflection resin sheet was prepared. The sheet forming was performed using a doctor blade with a clearance of 200 μm and a winding speed of 15 cm/min.

### (n) Preparation of Composite Material Vibrator and Evaluation of Electrical Characteristics Thereof

As shown in FIGS. 1 and 2, a piezoelectric resonator 2 and reflective layers 3 and 4 each composed of the acoustic reflection resin sheet removed from the carrier film were laminated with holding components 5 and 6, and the resulting laminate was cured at 150° C. for one hour while being pressed. Subsequently, outer electrodes 14 and 15 were formed to prepare a composite material vibrator. Each of the acoustic reflection resin sheets was adjusted such that the thickness of the resin sheet after curing was about λ/4 wherein λ represents an oscillation wavelength of the piezoelectric resonator. As the electrical characteristics of the resulting composite material vibrator, the maximum value of the phase was measured. When the maximum value of the phase is large, the electrical characteristics are excellent. When the maximum value of the phase was about 78 degrees or more, the sample was evaluated as “Good”. When the maximum value of the phase was about 78 degrees or less, the sample was evaluated as “Not good”.

### (o) Bleeding

The acoustic reflection resin sheet prepared in section (m) was aligned between glass substrates and laminated. The laminate was then cured with a special fixture under pressure at 150° C. for one hour. Subsequently, the width of bleeding from the glass substrates was measured with a length measuring device to evaluate the bleeding. When the width of the bleeding was about 3 mm or less, the sample was evaluated as “Good”. When the width of the bleeding was about 3 mm or more, the sample was evaluated as “Not good”.

### (p) Adhesiveness

The adhesiveness of the composite material vibrator prepared in section (n) was evaluated by a die shear test. Regarding the adhesiveness, when the adhesive strength was about 5N, the sample was evaluated as “Good”. When the adhesive strength was about 5N or less, the sample was evaluated as “Not good”.

### (q) Preparation of Resin Sheet

As Comparative Example 1, a bisphenol-A epoxy resin (epoxy equivalent= 190 g/eq) and o-cresol novolak epoxy resin (epoxy equivalent= 215 g/eq) that serve as thermosetting resins, phenol novolak (OH equivalent= 105 g/eq) serving as a curing agent, a polyvinyl butyral resin (weight-average molecular weight: 50,000) serving as a thermoplastic resin, and methyl ethyl ketone serving as a solvent were mixed with a planetary mixer for one hour to prepare a slurry. The o-cresol novolak epoxy resin and the polyvinyl butyral resin were dissolved in methyl ethyl ketone serving as a solvent in advance and used. The resulting slurry was subjected to vacuum deaeration. Subsequently, a sheet forming was performed by applying the slurry on a carrier film (PET, thickness: 50 μm) at 50° C. so that the surface coated with the silicone was disposed at the upper side. Thus, a reflection resin sheet was prepared. The sheet forming was performed using a doctor blade with a clearance of about 200 μm and a winding speed of about 15 cm/min, for example.

### (r) Preparation of Composite Material Vibrator and Evaluation of Electrical Characteristics Thereof

As shown in FIGS. 1 and 2, a piezoelectric resonator 2 and reflective layers 3 and 4 composed of the resin sheet removed from the carrier film were laminated with holding components 5 and 6, and the resulting laminate was cured at 150° C. for one hour while being pressed. Subsequently, outer electrodes 14 and 15 were formed to prepare a composite material vibrator. The acoustic reflection resin sheet was adjusted such that the thickness of the resin sheet after curing was about λ/4 wherein λ represents an oscillation wavelength of the piezoelectric resonator. As the electrical characteristics of the resulting composite material vibrator, the maximum value of the phase was measured. When the maximum value of the phase is large, the electrical characteristics are excellent. When the maximum value of the phase was about 78 degrees or more, the sample was evaluated as “Good”. When the maximum value of the phase was about 78 degrees or less, the sample was evaluated as “Not good”.

### (s) Preparation of Liquid Epoxy Resin Composition

As Comparative Example 2, a p-aminophenol epoxy resin (epoxy equivalent= 97 g/eq), an epoxy-imidazole adduct serving as a curing agent, fine silica particles (hydrophobic-treated silica, primary particle size: 16 nm), and a silicone resin powder (polymethylsilsesquioxane, average particle size: 2 μm) serving as a silicone compound were mixed with a planetary mixer for one hour to prepare a liquid epoxy resin composition.

### (t) Preparation of Composite Material Vibrator and Evaluation of Electrical Characteristics Thereof

As shown in FIGS. 1 and 2, the liquid epoxy resin composition prepared in section (l) was applied on a piezoelectric resonator 2 with a dispenser, and a holding component is then laminated thereon. Furthermore, the liquid epoxy resin composition prepared in section (l) was applied on a holding component 6 with the dispenser and the holding component 6 was then laminated on the piezoelectric resonator 2. Thus, the liquid epoxy resin composition was applied between the piezoelectric resonator 2 and the holding component 5 and between the piezoelectric resonator 2 and the holding component 6. The laminate was then cured at 150° C. for one hour while being pressed. Subsequently, a composite material vibrator was prepared as in the case of the resin and evaluated.

Table 5 shows the evaluation results. In Table 5, the samples marked with symbol * are out of the range of preferred embodiments of the present invention and the other sample is within the range of preferred embodiments of the present invention.

TABLE 5

| | | | * | * |
|---|---|---|---|---|
| Sample No. | | 19 | 20 | 21 |
| Thermosetting | Bisphenol-A epoxy resin | 9.0 | 9.0 | — |
| resin | o-Cresol novolak epoxy resin | 1.5 | 1.5 | — |
| | p-Aminophenol epoxy resin | — | — | 100 |
| Curing agent | Phenol novolak | 5.2 | 5.2 | — |
| | Epoxy-imidazole adduct | — | — | 20 |
| Thermoplastic | Polyvinyl butyral resin | 6.0 | 6.0 | — |
| resin | | | | |
| Additive | Silicone compound | 23.5 | — | 60 |
| | Fine silica particles | — | — | 2 |
| Solvent | Methyl ethyl ketone | 100 | 100 | — |

| | | | |
|---|---|---|---|
| Electrical characteristics | Good | Not | Good |
| | | good | |
| Bleeding | Good | Good | Not |
| | | | good |
| Adhesiveness | Good | Good | Good |

Referring to Table 5, Sample No. 19 including the acoustic reflection resin sheet was excellent in electrical characteristics because of the presence of the silicone compound as compared with Sample No. 20, which did not contain the silicone compound. In addition, in view of the bleeding, Sample No. 19 was superior to Sample No. 21, which included the liquid epoxy resin composition. The possible reason for this is as follows. Since the liquid epoxy resin composition had a high flowability, the bleeding significantly occurred. In contrast, since the acoustic reflection resin sheet had a low flowability, the bleeding was suppressed.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-10. (canceled)

11. A composite material vibrator comprising:
a vibrating component that is composed of a material having a first acoustic impedance Z₁ and that defines a vibration source;
a reflective layer that is composed of a cured product of a resin composition including at least a curing agent, a silicone compound, and a curable resin that is curable by heat or light, the cured product having a second acoustic impedance Z₂ that is lower than the first acoustic impedance Z₁, the reflective layer being connected to the vibrating component; and
a holding component that is composed of a material having a third acoustic impedance Z₃ that is higher than the second acoustic impedance Z₂, the holding component being connected to surfaces of the reflective layer, the surface being opposite to the surface connected to the vibrating component; wherein
vibration propagated from the vibrating component to the reflective layer is reflected at an interface between the reflective layer and the holding component.

12. The composite material vibrator according to claim 11, wherein the curable resin is an epoxy resin.

13. The composite material vibrator according to claim 11, wherein the silicone compound is included in the resin composition in an amount of about 6 percent by weight to about 60 percent by weight.

14. The composite material vibrator according to claim 11, wherein the silicone compound is a silicone resin powder.

15. The composite material vibrator according to claim 11, wherein the silicone compound is a silicone rubber powder coated with a polyorganosilsesquioxane cured product.

16. The composite material vibrator according to claim 11, wherein the sound velocity in the reflective layer at 5 MHz is about 2,600 m/s or less and the damping coefficient of the reflective layer at 5 MHz is about 3.5 dB/mm or less.

17. The composite material vibrator according to claim 11, wherein the vibrating component is a piezoelectric vibrating element.

18. A method for producing a composite material vibrator, comprising the steps of:
providing a vibrating component that defines a vibration source;
providing a holding component;
preparing an uncured resin composition containing at least a curing agent, a silicone compound, and a curable resin that is curable by heat or light;
laminating the vibrating component and the holding component with the uncured resin composition; and
curing the uncured resin composition to form a reflective layer that is connected to the vibrating component and the holding component; wherein
the vibrating component is formed of a material having a first acoustic impedance Z₁, the cured resin composition defining the reflective layer has a second acoustic impedance Z₂ that is lower than the first acoustic impedance Z₁, and the holding component is formed of a material having a third acoustic impedance Z₃ that is higher than the second acoustic impedance Z₂; and
vibration propagated from the vibrating component to the reflective layer is reflected at an interface between the reflective layer and the holding component.

19. The method for producing the composite material vibrator according to claim 18, wherein the curing is performed by heating.

20. The method for producing the composite material vibrator according to claim 18, wherein the curable resin is an epoxy resin.

21. The method for producing the composite material vibrator according to claim 18, wherein the silicone compound is included in the resin composition in an amount of about 6 percent by weight to about 60 percent by weight.

22. The method for producing the composite material vibrator according to claim 18, wherein the silicone compound is a silicone resin powder.

23. The method for producing the composite material vibrator according to claim 18, wherein the silicone compound is a silicone rubber powder coated with a polyorganosilsesquioxane cured product.

24. The method for producing the composite material vibrator according to claim 18, wherein the sound velocity in the reflective layer at 5 MHz is about 2,600 m/s or less and the damping coefficient of the reflective layer at 5 MHz is about 3.5 dB/mm or less.

25. The method for producing the composite material vibrator according to claim 18, wherein the vibrating component is a piezoelectric vibrating element.

26. A method for producing a composite material vibrator, comprising the steps of:
providing a vibrating component that defines a vibration source;
providing a holding component;
preparing a resin sheet containing at least a curable resin, a curing agent, and a silicone compound;
disposing the resin sheet on the vibrating component and the holding component; and
curing the resin sheet to form a reflective layer that is connected to the vibrating component and the holding component; wherein
the vibrating component is formed of a material having a first acoustic impedance Z₁, the resin sheet defining the reflective layer has a second acoustic impedance Z₂ that is lower than the first acoustic impedance Z₁, and the holding component is formed of a material having a third acoustic impedance Z₃ that is higher than the second acoustic impedance Z₂; and
vibration propagated from the vibrating component to the reflective layer is reflected at an interface between the reflective layer and the holding component.

27. The method for producing the composite material vibrator according to claim 26, wherein the curing is performed by heating.

28. The method for producing the composite material vibrator according to claim 26, wherein the curable resin is an epoxy resin.

29. The method for producing the composite material vibrator according to claim 26, wherein the silicone compound is included in the resin composition in an amount of about 6 percent by weight to about 60 percent by weight.

30. The method for producing the composite material vibrator according to claim 26, wherein the silicone compound is a silicone resin powder.

31. The method for producing the composite material vibrator according to claim 26, wherein the silicone compound is a silicone rubber powder coated with a polyorganosilsesquioxane cured product.

32. The method for producing the composite material vibrator according to claim 26, wherein the sound velocity in the reflective layer at 5 MHz is about 2,600 m/s or less and the damping coefficient of the reflective layer at 5 MHz is about 3.5 dB/mm or less.

33. The method for producing the composite material vibrator according to claim 26, wherein the vibrating component is a piezoelectric vibrating element.
